(19) United States
(12) Patent Application Publication
(10) Pub. No.: US 2026/0018369 A1
(43) Pub. Date: Jan. 15, 2026

(54) LENS WITH A SCANNING SYSTEM, CHARGED PARTICLE BEAM APPARATUS, AND METHOD OF SCANNING A CHARGED PARTICLE BEAM

(71) Applicant: ICT Integrated Circuit Testing Gesellschaft für Halbleiterprüftechnik mbH, Heimstetten (DE)

(72) Inventors: Matthias Firnkes, Walpertskirchen (DE); Ivo Liska, Haar (DE)

(73) Assignee: ICT Integrated Circuit Testing Gesellschaft für Halbleiterprüftechnik mbH, Heimstetten (DE)

(21) Appl. No.: 18/773,470

(22) Filed: Jul. 15, 2024

(51) Int. Cl. H01J 37/141; H01J 37/147; H01J 37/28

(52) U.S. Cl. CPC H01J 37/141; H01J 37/1475; H01J 37/28

(57) ABSTRACT

A lens configured for a charged particle beam apparatus is described. The lens includes a first electrode configured to be charged to a first potential and a liner tube coupled to the first electrode, the liner tube includes at least a first conductive portion; a ceramic portion upstream of the first conductive portion; and one or more coating layers disposed on the ceramic portion in electrical contact with the first conductive portion. The lens includes a second electrode configured to be charged to a second potential, the first potential and the second potential generating a lens effect between the first conductive portion and the second electrode; and a magnetic deflector having at least a first pair of scan coils provided outside of the liner tube.

### TECHNICAL FIELD

Embodiments described herein relate to charged particle beam apparatuses for use in review, inspection, defect detection, and/or critical dimensioning applications. Embodiments of the present disclosure relate to scanning of a charged particle beam, and particularly to fast scanning with a magnetic scan deflector. Specifically, embodiments of the present disclosure relate to a lens configured for a charged particle beam apparatus, a liner tube configured to be disposed in a lens of a charged particle beam apparatus, a scanning charged particle beam apparatus, and method of generating an image of a portion of a specimen.

### BACKGROUND

Charged particle multi-beam systems have many uses, such as imaging or inspection of semiconductor devices with nanometer scale features. Modern semiconductor technology is highly dependent on an accurate control of the various processes used during the production of integrated circuits. Accordingly, semiconductor wafers are inspected in order to detect problems. Furthermore, a mask or reticle can be subject to inspection in order to make sure that the mask or reticle accurately defines a desired pattern.

Scanning electron microscopes (SEM) have been used to image or inspect wafers. The surface of the wafer can be scanned using a finely focused electron beam. When the electron beam irradiates the wafer, secondary electrons and/or backscattered electrons, i.e. signal electrons, are generated and can be detected. A defect at a location on the wafer can be detected by comparing an intensity signal of the secondary electrons to, for example, a reference signal corresponding to the same location on the pattern. An image can be generated for e.g. critical dimensioning applications.

Wafer and mask defect inspection, imaging, critical dimensioning measurements or the like in semiconductor technology benefits from high resolution and fast inspection tools, which may cover full wafer/mask application and/or hot spot inspection. Electron beams can be used to provide high resolution inspection of samples so as to be able to detect small defects. In particular, from the 20 nm node and beyond, the high-resolution potential of electron beam-based imaging tools is in demand to detect many defects of interest.

The throughput of e.g. a scanning electron microscope (SEM) depends inter alia on the scan speed. The scan speed is the speed with which a charged particle beam can be moved across the specimen surface to create an image. An asymmetric sawtooth signal (e.g. a current signal) can be applied to scan deflector coils. The signal includes a fast retrace and a slower line scan portion. To create an image, the scan signal beneficially has a certain linearity before acquiring the image. This time-to-linearity (TTL) can be in the order of 6-10 μs. The TTL may be in the same time range as the shortest desired line scanning times are in the same order magnitude.

Embodiments of the present disclosure provide an improved time-to linearity for a scanning charged particle beam apparatus and for methods of scanning a charged particle beam in a scanning charged particle beam apparatus.

### SUMMARY

In light of the above, a lens configured for a charged particle beam apparatus, a liner tube configured to be disposed in a lens of a charged particle beam apparatus, a scanning charged particle beam apparatus, and method of generating an image of a portion of a specimen are provided according to the independent claims. Further aspects, advantages, and beneficial features are apparent from the dependent claims, the description, and the accompanying drawings.

According to an embodiment, a lens configured for a charged particle beam apparatus is provided. The lens includes a first electrode configured to be charged to a first potential and a liner tube coupled to the first electrode, the liner tube includes at least a first conductive portion; a ceramic portion upstream of the first conductive portion; and one or more coating layers disposed on the ceramic portion in electrical contact with the first conductive portion. The lens includes a second electrode configured to be charged to a second potential, the first potential and the second potential generating a lens effect between the first conductive portion and the second electrode; and a magnetic deflector having at least a first pair of scan coils provided outside of the liner tube.

According to an embodiment, a liner tube configured to be disposed in a lens of a charged particle beam apparatus is provided. The liner tube includes at least a first conductive portion; a ceramic portion adjacent the first conductive portion; and one or more coating layers disposed on the ceramic portion in electrical contact with the first conductive portion, wherein the first conductive portion is configured as a lens electrode.

According to an embodiment, a scanning charged particle beam apparatus is provided. The scanning charged particle beam apparatus includes a charged particle source configured to emit a primary charged particle beam; a stage configured to support a specimen to be irradiated with the primary charged particle beam; and a lens according to any of the embodiments of the present disclosure, and configured to focus the primary charged particle beam on the specimen, wherein the magnetic deflector is configured to scan the primary charged particle beam over the specimen.

According to an embodiment, a method of generating an image of a portion of a specimen with a scanning charged particle beam apparatus is provided. The method includes biasing a first electrode to provide a first potential to a first conductive portion through one or more coated layers disposed on a ceramic portion of a liner tube; biasing a second electrode to a second potential to generate a lens effect between the first conductive portion and the second electrode; and scanning a primary charged particle beam over the specimen with a magnetic deflector disposed outside of the liner tube.

Embodiments are also directed at apparatuses for carrying out the disclosed methods and include apparatus parts for performing each described method features. The method features may be performed by way of hardware components, a computer programmed by appropriate software, by any combination of the two or in any other manner. Furthermore, embodiments are also directed at methods which can be carried out by the described apparatus. Embodiments include method features for carrying out every function of the apparatus.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following.

FIG. 1 shows a schematic view of a charged particle beam apparatus according to embodiments described herein and having a lens and a liner tube according to embodiments described herein;

FIG. 2A illustrates a graph of a scan ramp, e.g. a magnetic field as a function of time to illustrate advantages of embodiments of the present disclosure;

FIG. 2B illustrates an enlarged view of the graph shown in FIG. 2A;

FIG. 3 shows a schematic view of a liner tube according to embodiments described herein;

FIG. 4A shows a schematic view of a portion of a scanning charged particle beam apparatus illustrating liner tube and coils of a magnetic deflector according to embodiments described herein;

FIG. 4B shows a schematic view of a coil of a magnetic deflector according to embodiments described herein; and

FIG. 5 shows a flowchart illustrating methods of generating an image of a portion of the specimen with a scanning charged particle beam apparatus according to embodiments described herein.

### DETAILED DESCRIPTION

Reference will now be made in detail to the various embodiments, one or more examples of which are illustrated in the figures. Within the following description of the drawings, the same reference numbers refer to same components. The differences with respect to individual embodiments are described. Each example is provided by way of explanation and is not meant as a limitation. Further, features illustrated or described as part of one embodiment can be used on or in conjunction with other embodiments to yield yet a further embodiment. The description is intended to include the modifications and variations.

Without limiting the scope of protection of the present application, in the following, the charged particle beam apparatus or components thereof can be referred to as a charged particle beam apparatus having a primary electron beam, which may include components for the detection of secondary or backscattered electrons. Embodiments can include apparatuses and components that may utilize another primary charged particle beam and/or that may detect secondary and/or backscattered charged particles in the form of electrons, ions, photons, X-rays and/or other signals which may be used to obtain a specimen image. As described herein, discussions and descriptions relating to the detection are exemplarily described with respect to electrons in scanning electron microscopes. Other types of charged particles, e.g. positive ions, can be detected in a variety of different instruments. A primary charged particle beam can be generated by a charged particle source and can be guided to a specimen to be inspected and/or imaged.

According to embodiments herein, which can be combined with other embodiments, a signal (charged particle) beam can be referred to as a beam of secondary particles, e.g. secondary and/or backscattered electrons. Typically, the signal beam is generated by the impingement of the primary beam on a specimen or by backscattering of the primary beam from the specimen. A “specimen” or “sample” as referred to herein, includes, but is not limited to, semiconductor wafers, semiconductor workpieces, photolithographic masks and other workpieces such as memory disks, other substrates, or the like. Embodiments may be applied to any workpiece on which material is deposited or which is structured. “Scanning” as used herein, refers to motion along at least one direction, such as movement or scanning of the primary beam, such as for irradiating a sample.

Embodiments of the present disclosure increase the throughput of e.g. a scanning electron microscope (SEM) by increasing the scan speed. The scan speed is increased by reducing the time-to-linearity of the scan signal. A liner tube is provided with a ceramic portion having one or more coatings layers. Additionally or alternatively, one or more coils of magnetic deflector can be provided with split wires, particularly in an overlap region, i.e. an overlap region between x-direction and y-direction coils. Eddy currents can be reduced to reduce the time-to-linearity of the scan signal.

According to some embodiments, which can be combined with other embodiments described herein, the apparatus and methods are configured for or are applied for electron beam inspection, for critical dimensioning applications and defect review applications.

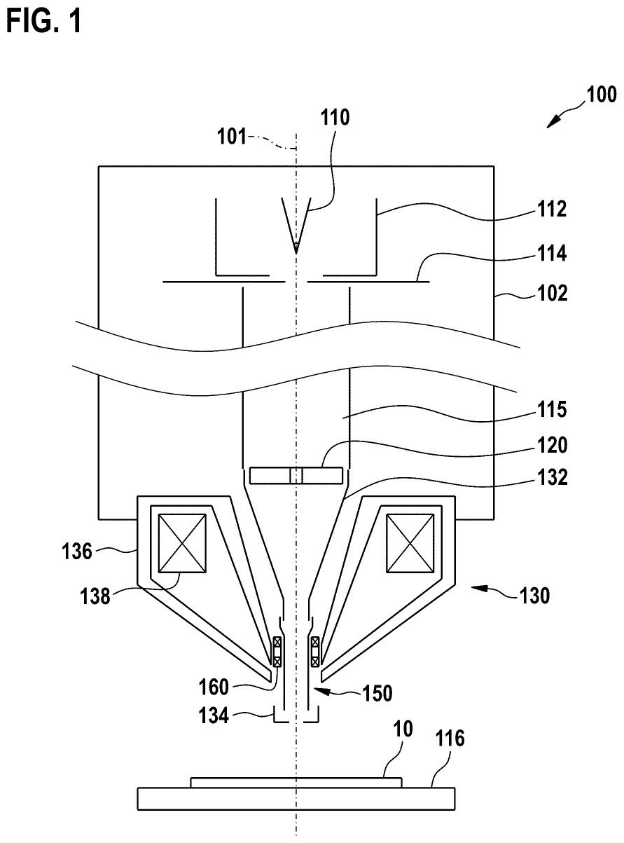

FIG. 1 shows a scanning charged particle beam apparatus 100. The scanning charged particle beam apparatus 100 includes a charged particle source 110, which can generate charged particles which are directed or guided along an optical axis 101 towards the specimen 10. The specimen 10 can be supported on a specimen stage 116, i.e. a support table for the substrate to be imaged or inspected. A suppressor 112 may be provided adjacent the charged particle source. Charged particles, such as electrons, can be accelerated towards an anode 114. A beam boost tube 115 can be biased to provide a high energy for the primary charged particle beam, particularly while travelling through the column 102. A primary charged particle beam, such as a primary electron beam is emitted for imaging or inspection of the specimen 10. The charged particle source 110 and further electro-optical components (not shown) can be provided in the column 102. A vacuum can be provided in the column 102.

According to some embodiments, which can be combined with other embodiments described herein, the further electro-optical components can include one or more of a condenser lens, a stigmator, alignment deflectors, a beam separator to separate a primary beam from a signal beam, apertures, such as beam limiting apertures, and a detector 120. The detector 120 can be an on-axis detector, as shown in FIG. 1. The detector 120 detects signal particles generated upon impingement of the primary electron beam on the specimen 10, particularly for inspecting or imaging of the specimen. Additionally or alternatively, an off-axis detector can be provided.

The primary charged particle beam is focused by the lens 130 on the specimen 10. For example, the lens 130 can be an objective lens. The lens includes a first electrode 132. The first electrode 132 can be charged to a first potential. Further, the lens includes a second electrode 134. The second electrode 134 can be charged to a second potential, particularly a decelerating potential for decelerating and focusing the primary charged particle beam. The lens further includes a liner tube 150 according to embodiments of the present disclosure. The magnetic deflector 160 having at least the first pair of scan coils is provided outside of the liner tube.

According to some embodiments, which can be combined with other embodiments described herein, the lens 130 may further include a pole piece 136 and a coil 138 for generating a magnetic focusing field. Accordingly, the lens 130 can be a combined electrostatic-magnetic lens. According to some embodiments, which can be combined with other embodiments described herein, a lens according to embodiments of the present disclosure can be an objective lens, can further include a lens coil and a pole piece configured to guide the magnetic field of the lens coil, wherein the liner tube being disposed within the pole piece.

According to an embodiment, a lens configured for a charged particle beam apparatus is provided. The lens includes a first electrode configured to be charged to a first potential and a liner tube coupled to the first electrode. The liner tube includes at least a first conductive portion, a ceramic portion upstream of the first conductive portion, and one or more coating layers disposed on the ceramic portion in electrical contact with the first conductive portion. The lens includes a second electrode configured to be charged to a second potential, the first potential and the second potential generating a lens effect between the first conductive portion and the second electrode, and a magnetic deflector having at least a first pair of scan coils provided outside of the liner tube.

Embodiments of the present disclosure provide a liner tube, a lens having a liner tube, a charged particle beam apparatus having a liner tube, and a method of operating a charged particle beam apparatus, wherein the scan speed of a magnetic deflector to deflect the primary electron beam across the sample surface is increased. The bandwidth can be increased inter alia by reducing Eddy currents, particularly Eddy currents at the liner tube inside the scan coils of the magnetic deflector. The Eddy currents introduce a non-linearity to the scan ramp, i.e. the signal provided to a scan coil. A further contribution to the non-linearity of the scan ramp can be a width of the copper lines of scan coils, particularly if scan coils for an x-direction and the scan coils for a y-direction overlap.

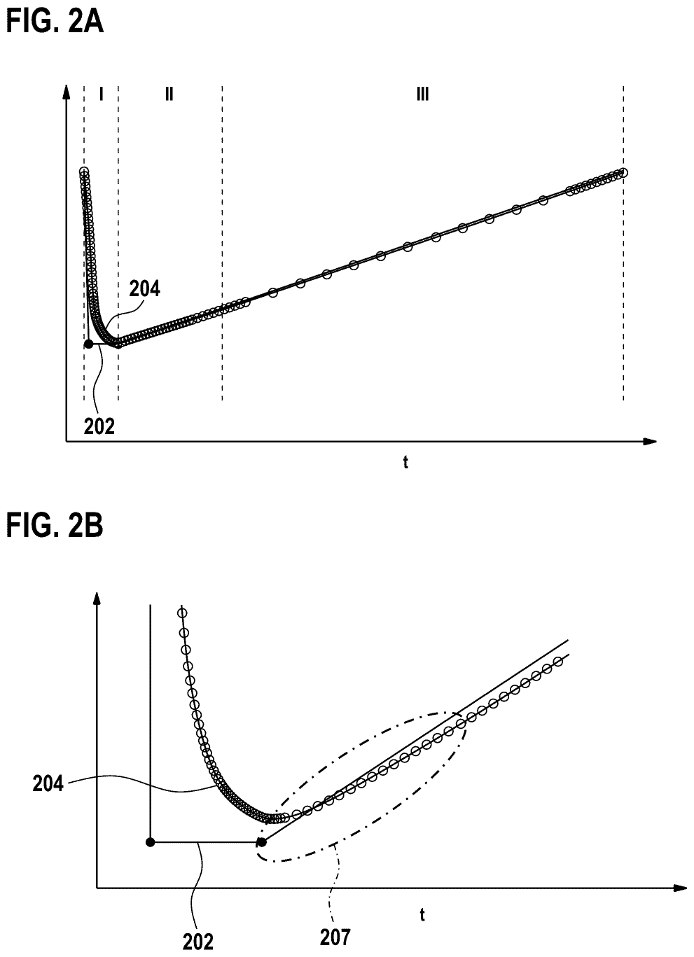

FIG. 2A illustrates a graph of a scan ramp. A current signal 202 provided to magnetic deflector is shown. Further, the magnetic field response 204 is shown as a function of time. FIG. 2B shows an enlarged view of a portion of FIG. 2A. During the first time period I, the primary electron beam is retraced, i.e. a fast change in current signal is provided. Time period II corresponds to a pre-scan time period, during which there is a non-linear regime 207. The active line scan is provided during time period III. As can be seen, the time period III can be in the same order of magnitude as compared to the time period II. For small field of views, i.e. small imaging areas, the active line scan region can be further reduced, such that the pre-scan time period and the time period for the active line scan can even be in a comparable range.

Accordingly, a significant amount of time cannot be utilized for imaging, which reduces throughput.

For a magnetic deflector, scan coils are used to deflect the electron beam across the sample surface. A variable magnetic dipole field is excited by a current waveform. A rapidly changing magnetic field induces Eddy currents in electrically conductive materials. The quickly changing magnetic deflection field during time period I introduces Eddy currents, which act against the deflection field, thus, distorting linearity.

Embodiments of the present disclosure provide a liner tube having a ceramic portion and one or more coating layers disposed on the ceramic portion. Thus, the electrical conductivity, the magnetic permittivity, and the geometry, e.g. the thickness of the conductive portion of the liner, can be provided in a manner for reducing Eddy currents.

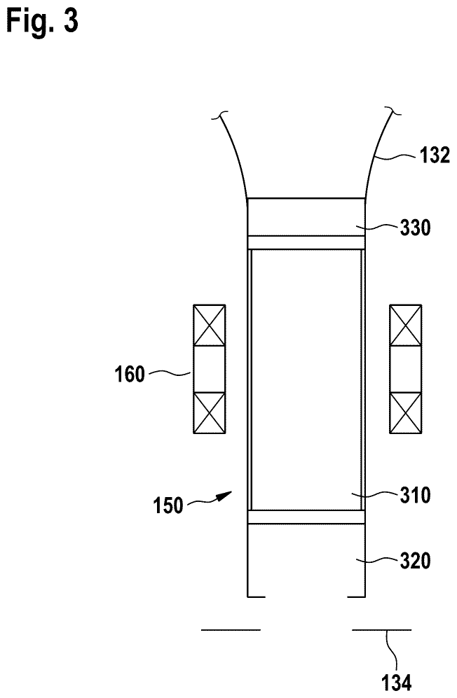

FIG. 3 shows a liner tube 150 provided in electrical contact with a first electrode 132. Further, a second electrode 134 is shown. The liner tube 150 includes a ceramic portion 310 and a first conductive portion 320. Further, the liner tube may include a second conductive portion 330. An electrostatic lens field is provided between the first conductive portion and the second electrode. The first conductive portion is electrically connected to the first electrode. Thus, a first potential provided to the first electrode is provided to the first conductive portion for generation of the lens field. According to some embodiments, which can be combined with other embodiments, the first conductive portion may also include an electrically connected insert forming the lens electrode or a portion of the lens electrode.

A magnetic deflector 160, e.g. a pair of saddle deflection coils, surround the liner tube 150. According to some embodiments, which can be combined with other embodiments described herein, the liner tube may separate the vacuum region of the SEM from atmosphere.

The impact of the liner on the magnetic field is reduced by having a ceramic portion coated with one or more coating layers being conductive. A ceramic portion can be coated with one or more metal layers. For example, the ceramic portion can be Al2O3, AlN, Si3N4, or other machinable glass-ceramic, like Macor, i.e. a fluorphlogopite mica in a borosilicate glass matrix. The one or more coatings can be titanium alloys. Thus, a thin conductive coating with a material with moderate electrical conductivity can be provided. The first conductive portion 320 can include or can be made of titanium. Further, the second conductive portion 330 can include or can be made of titanium. The conductive portions may be soldered to the ceramic portion. Alternatively, the conductive portions may be connected via spring like elements. An electrical connection is provided from the first electrode, via the optional second conductive portion, via the one or more coating layers to the first conductive portion 320.

According to some embodiments, which can be combined with other embodiments described herein, having one or more conductive coatings on the inside of the liner tube further reduces the risk of charging of the liner tube, wherein charges accumulating on the liner tube may interfere with the primary charged particle beam or may influence a signal beam.

According to some embodiments, which can be combined with other embodiments described herein, the one or more coating layers can be two or more coating layers. For example, the two or more coating layers can be a carbide of a material, such as titanium, and a nitride of the material. For example, the ceramic portion can be coated or partially coated with a layer of TiN and a layer of TiC. A first coating layer of the two or more coating layers can be titanium nitride and a second coating layer of the two or more coating layers can be titanium carbide. According to some embodiments, which can be combined with other embodiments described herein, the one or more coating layers can be disposed on the inside of the ceramic portion. Additionally or alternatively, the conductivity of the one or more coating layers, i.e. the conductivity of the combination of the one or more coating layers, can be from 1E5 S/m to 3E6 S/m. The thickness of each of the one or more coating layers can be from 1 μm to 5 μm.

Having two or more coatings, for example titanium nitride and titanium carbide, can beneficially provide a uniform and stable coating with a conductivity in a beneficial range, particularly not too high conductivities. Further, a thin conductive layer can be provided, with a thickness of e.g. a few μm. Eddy currents can be reduced as compared to a titanium liner.

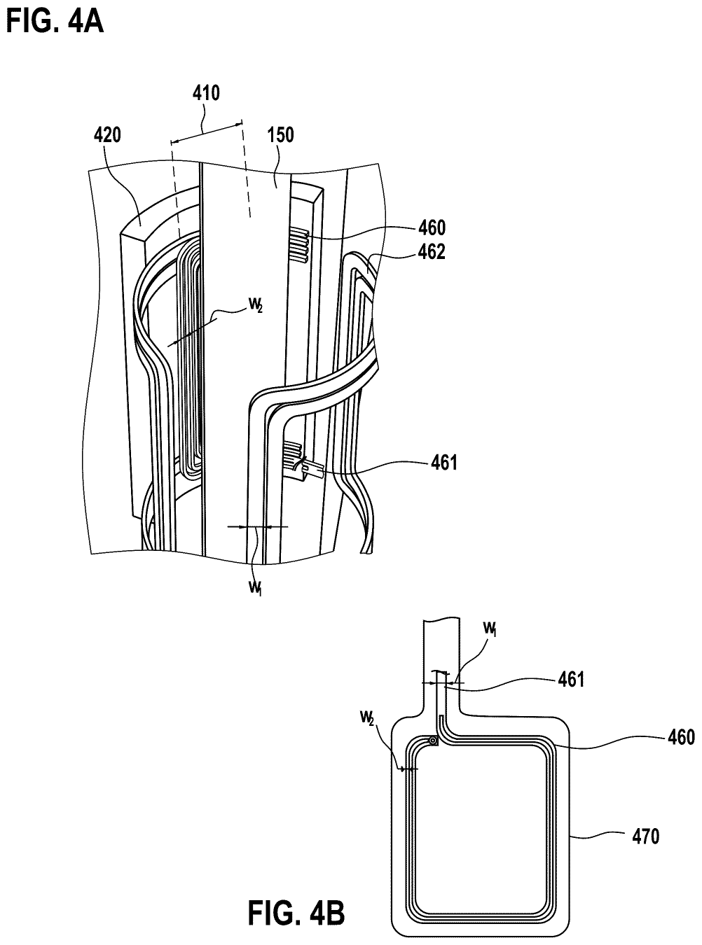

FIG. 4 shows an arrangement of scan coils having a first scan coil 460 of the first pair of scan coils and second scan coils 462 of a second pair of scan coils. The first pair of scan coils can, for example, deflect the beam in a first direction, such as the x-direction. The second pair of scan coils deflect the beam in a second direction, such as the y-direction. The scan coils are provided outside of the liner tube 150. Further, a ferrite tube 420 can surround the scan coils. The scan coils can be provided as thin wires provided on a flexible printed circuit board (PCB), for example PCB 470 shown in FIG. 4B.

According to some embodiments, which can be combined with other embodiments described herein, the first pair of scan coils are arranged to deflect a charged particle beam within the charged particle beam column in one direction. A magnetic deflector can include at least a second pair of scan coils. Particularly, the second pair of scan coils can be configured to deflect the charged particle beam in a second direction different, e.g. perpendicular, to the first direction.

As shown in FIG. 4A, according to some embodiments, which can be combined with other embodiments described herein, the first pair of scan coils and second pair of scan coils can partially overlap, e.g. along a polar coordinate. First conductors of the first pair of scan coils and second conductors of the second pair of scan coils partially overlap. This is indicated by overlap region 410 in FIG. 4A. As exemplarily shown in FIG. 4A, the magnetic deflector may provide two magnetic dipoles. According to some embodiments, which can be combined with other embodiments described herein, the plurality of scan coils forming an octupole may be provided. For example, 8 coils can be provided, particularly 8 racetrack coils can be provided.

The second scan coils 462 shown in FIG. 4A have windings with a width w1 of the wire. The first scan coil 460 or the first scan coils, respectively, show windings with split wires. The wires of the first scan coil can have a second width w2. The second width w2 is smaller than the first width w1. The reduced wire cross-section reduces Eddy currents. According to embodiments of the present disclosure the first scan coils and the second scan coils can include split wires as shown for the first scan coil 460 in FIG. 4A. For example, the wires can be made of copper.

According to some embodiments, which can be combined with other embodiments described herein, a coil of the first pair of scan coils can include two connecting portions. FIG. 4B shows a PCB 470 with a first coil 460 provided thereon. The coil has a connection portion 461 with a first width w1 and a coil portion with a second width w2 smaller than the first width. For example, the connection portion can have a width similar to the first width w1 of the second scan coils 462, wherein the second scan coil is only exemplarily shown in FIG. 4A and the scan coils may both have split wires. Further, a coil of the first pair of scan coils (and the second pair of scan coils (not shown)) includes a coil portion with split wires (as shown in FIGS. 4A and 4B) between the two connecting portions, wherein the split wires having a second width smaller than the first width. According to some embodiments, the second width can be about one half to one third of the first width. Having the connection portions at a larger width allows a higher current without generating heat in the wire. Further, having split wires, i.e. split thinner wires, also allows higher currents without generating heat in the wire.

As shown in FIG. 4B, the winding of the coil may have an end at a feedthrough to the opposite side of the PCB. A second connection portion of the scan coil can be provided at an opposing side of the PCB. The second connection portion can have width equal to or similar than the first width w1.

FIG. 4A shows two windings of a coil. FIG. 4B shows one winding of a coil. According to some embodiments, which can be combined with other embodiments described herein, a coil may have N windings, N being an integer 1<=N<=10. Further, additionally or alternatively each winding can have a number of n split wires, n being an integer 2<=n<=6.

According to some embodiments, the coil or a portion of the coil can be provided on one side of the PCB. Another portion may be provided on the opposing side of the PCB, for example, when having an electrical connection through the PCB. The another portion may be a connection portion and/or may be a further winding of the coil. FIG. 4B shows one coil 460 on a PCB 470. According to some embodiments, which can be combined with other embodiments described herein, a connection portion on one side of the PCB may be forwarded to a second PCB of a second coil of a pair of scan coils. Accordingly, a pair of scan coils can be connected in series. Both scan coils of a pair of scan coils can be connected to one current supply.

Some embodiments of the present disclosure provide thin coil windings, for example, on one or more flexible printed circuit boards (PCB), in combination with the thin coatings on a ceramic. Eddy currents can be reduced, which increases the bandwidth of the scanning charged particle beam apparatus. Accordingly, a time period II (see FIG. 2A) corresponding to a pre-scan time period can be reduced, which in turn results in higher throughput.

According to an embodiment, a lens configured for a charged particle beam apparatus is provided. The lens includes a first electrode configured to be charged to a first potential; a liner tube coupled to the first electrode, the line tube including at least a first conductive portion. The lens includes a second electrode configured to be charged to a second potential, the first potential and the second potential generating a lens effect between the first conductive portion and the second electrode and a magnetic deflector having at least a first pair of scan coils provided outside of the liner tube. A coil of the first pair of scan coils includes two connecting portions, at least one connecting portion having a first width and a coil portion with split wires between the two connecting portions, wherein the split wires have a second width smaller than the first width.

According to an embodiment, a magnetic deflector, particularly for scanning of a charged particle beam, can include at least a first pair of scan coils provided, e.g. outside of a liner tube. A coil of the first pair of scan coils includes two connecting portions, at least one connecting portion having a first width and a coil portion with split wires between the two connecting portions, wherein the split wires have a second width smaller than the first width.

The magnetic deflector can include at least a second pair of scan coils. Particularly, the second pair of scan coils can be configured to deflect the charged particle beam in a second direction different, e.g. perpendicular, to the first direction. According to some embodiments, first conductors of the first pair of scan coils and second conductors of the second pair of scan coils partially overlap. Further, additionally or alternatively, the magnetic deflector can provide two dipoles or can provide an octupole. A second width of the split wires can be about one half to one third of the first width of a connection portion or can be 1/nth in width or can be smaller than 1/nth in width if the wire is split into more than two split wires. Embodiments directed to a magnetic deflector having split wires or a lens with a magnetic deflector having split wires can be combined with other embodiments described herein, particularly having features aspects and details of the liner tube with one or more coating layers.

Embodiments described above particularly refer to the lens having a liner tube and a scanning charged particle beam apparatus having a liner tube. According to an embodiment, also a liner tube configured to be disposed in a lens of a charged particle beam apparatus is provided. The liner tube includes at least a first conductive portion; a ceramic portion adjacent the first conductive portion; and one or more coating layers disposed on the ceramic portion in electrical contact with the first conductive portion. The first conductive portion is configured as a lens electrode. The additional aspects, advantages, features of the liner tube described with respect to the lens and the scanning charged particle beam apparatus can be combined with the embodiments directed to the liner tube.

According to an embodiment, a scanning charged particle beam apparatus is provided. The scanning charged particle beam apparatus includes a charged particle source configured to emit a primary charged particle beam and a stage configured to support a specimen to be irradiated with the primary charged particle beam. The scanning charged particle beam apparatus further includes a lens according to any of the embodiments described herein. The lens including the magnetic deflector is configured to focus the charged particle beam on the specimen, wherein the magnetic deflector is configured to scan the primary charged particle beam over the specimen. According to some embodiments, the scanning charged particle beam apparatus further includes a beam boost tube extending at least partially through a column of the scanning charged particle beam apparatus in the direction from the charged particle source towards the lens. The beam boost tube can be electrically connected to the first electrode.

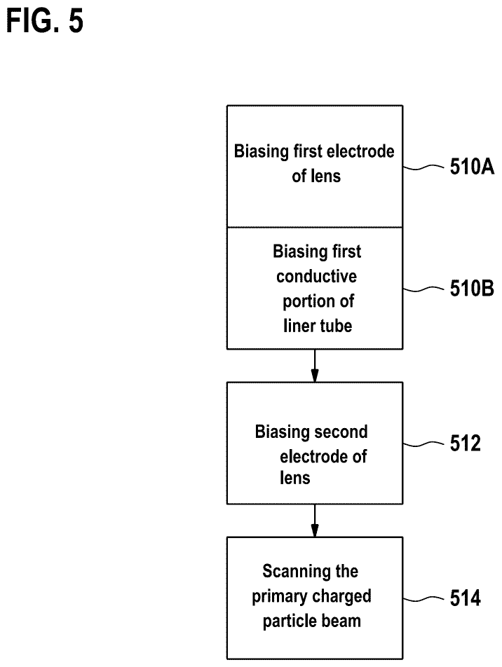

FIG. 5 shows a flow chart illustrating a method of generating an image of a portion of a specimen with a scanning charged particle beam apparatus. At operation 510A, the first electrode of the lens is biased, i.e. set on a first potential. Resulting there from, at operation 510B, a first conductive portion of the liner tube is biased to the first potential. Accordingly, the method includes biasing a first electrode to provide a first potential to a first conductive portion through one or more coated layers disposed on a ceramic portion of a liner tube. At operation 512 a second electrode is biased to a second potential to generate a lens effect between the conductive portion and the second electrode. Accordingly, a primary charged particle beam generated with a charged particle source of the scanning charged particle beam apparatus is focused on a specimen. At operation 514, the primary charged particle beam is scanned over the specimen with a magnetic deflector disposed outside of the liner tube.

The present disclosure discloses a plurality of embodiments, some of which are as described below: Embodiment 1. A lens configured for a charged particle beam apparatus, comprising: a first electrode configured to be charged to a first potential; a liner tube coupled to the first electrode, the liner tube comprising: at least a first conductive portion; a ceramic portion upstream of the first conductive portion; and one or more coating layers disposed on the ceramic portion in electrical contact with the first conductive portion; the lens comprising: a second electrode configured to be charged to a second potential, the first potential and the second potential generating a lens effect between the first conductive portion and the second electrode; and a magnetic deflector having at least a first pair of scan coils provided outside of the liner tube.

Embodiment 2. The lens according to embodiment 1, wherein the one or more coating layers are two or more coating layers.

Embodiment 3. The lens according to embodiment 2, wherein the two or more coating layers are a carbide of a material and a nitride of the material.

Embodiment 4. The lens according to embodiment 3, wherein the material is titanium and a first coating layer of the two or more coating layers is titanium nitride and a second coating layer of the two or more coating layers is titanium carbide.

Embodiment 5. The lens according to any of embodiments 1 to 4, wherein the one or more coating layers are disposed on an inside of the ceramic portion.

Embodiment 6. The lens according to any of embodiments 1 to 5, wherein an electric conductivity of the one or more coating layers is from 1E5 S/m to 3E6 S/m.

Embodiment 7. The lens according to any of embodiments 1 to 6, wherein a thickness of each of the one or more coating layers is from 1 μm to 5 μm.

Embodiment 8. The lens according to any of embodiments 1 to 7, wherein the first pair of scan coils are arranged to deflect a primary charged particle beam within the charged particle beam apparatus in a first direction.

Embodiment 9. The lens according to any of embodiments 1 to 7, wherein the magnetic deflector comprises: at least a second pair of scan coils.

Embodiment 10. The lens according to embodiment 8, wherein the magnetic deflector comprises: at least a second pair of scan coils configured to deflect the primary charged particle beam in a second direction different from the first direction.

Embodiment 11. The lens according to embodiment 10, wherein first conductors of the first pair of scan coils and second conductors of the second pair of scan coils partially overlap.

Embodiment 12. The lens according to any of embodiments 1 to 11, wherein the magnetic deflector provides two dipoles or provides an octupole.

Embodiment 13. The lens according to any of embodiments 1 to 12, wherein a coil of the first pair of scan coils includes two connecting portions, at least one connecting portion having a first width and a coil portion with split wires between the two connecting portions, wherein the split wires have a second width smaller than the first width.

Embodiment 14. The lens according to embodiment 13, wherein the second width is about one half to one third of the first width.

Embodiment 15. The lens according to any of embodiments 1 to 14, wherein the lens is an objective lens and further comprises: a lens coil; and a pole piece configured to guide a magnetic field of the lens coil, the liner tube being disposed within the pole piece.

Embodiment 16. A liner tube configured to be disposed in a lens of a charged particle beam apparatus, comprising: at least a first conductive portion; a ceramic portion adjacent the first conductive portion; and one or more coating layers disposed on the ceramic portion in electrical contact with the first conductive portion, wherein the first conductive portion is configured as a lens electrode.

Embodiment 17. A scanning charged particle beam apparatus, comprising: a charged particle source configured to emit a primary charged particle beam; a stage configured to support a specimen to be irradiated with the primary charged particle beam; and a lens according to any of embodiments 1 to 15 configured to focus the primary charged particle beam on the specimen, wherein the magnetic deflector is configured to scan the primary charged particle beam over the specimen.

Embodiment 18. The scanning charged particle beam apparatus of embodiment 17, further comprising: a beam boost tube extending at least partially through a column of the scanning charged particle beam apparatus in a direction from the charged particle source towards the lens, the beam boost tube being electrically connected to the first electrode.

Embodiment 19. A method of generating an image of a portion of a specimen with a scanning charged particle beam apparatus, comprising: biasing a first electrode to provide a first potential to a first conductive portion through one or more coated layers disposed on a ceramic portion of a liner tube; biasing a second electrode to a second potential to generate a lens effect between the first conductive portion and the second electrode; and scanning a primary charged particle beam over the specimen with a magnetic deflector disposed outside of the liner tube.

In light of the improved liner tube and/or the improved magnetic deflectors, the throughput of an SEM can be increased. More wafers per hour can be inspected or reviewed.

While the foregoing is directed to embodiments of the disclosure, other and further embodiments of the disclosure may be devised without departing from the scope thereof, and the scope thereof is determined by the claims that follow.

1. A lens configured for a charged particle beam apparatus, comprising:
a first electrode configured to be charged to a first potential;
a liner tube coupled to the first electrode, comprising:
at least a first conductive portion;
a ceramic portion upstream of the first conductive portion; and
one or more coating layers disposed on the ceramic portion in electrical contact with the first conductive portion;
a second electrode configured to be charged to a second potential, the first potential and the second potential generating a lens effect between the first conductive portion and the second electrode; and
a magnetic deflector having at least a first pair of scan coils provided outside of the liner tube.

2. The lens according to claim 1, wherein the one or more coating layers are two or more coating layers.

3. The lens according to claim 2, wherein the two or more coating layers are a carbide of a material and a nitride of the material.

4. The lens according to claim 3, wherein the material is titanium and a first coating layer of the two or more coating layers is titanium nitride and a second coating layer of the two or more coating layers is titanium carbide.

5. The lens according to claim 1, wherein the one or more coating layers are disposed on an inside of the ceramic portion.

6. The lens according to claim 1, wherein an electric conductivity of the one or more coating layers is from 1E5 S/m to 3E6 S/m.

7. The lens according to claim 1, wherein a thickness of each of the one or more coating layers is from 1 μm to 5 μm.

8. The lens according to claim 1, wherein the first pair of scan coils are arranged to deflect a primary charged particle beam within the charged particle beam apparatus in a first direction.

9. The lens according to claim 1, wherein the magnetic deflector comprises:
at least a second pair of scan coils.

10. The lens according to claim 8, wherein the magnetic deflector comprises:
at least a second pair of scan coils configured to deflect the primary charged particle beam in a second direction different from the first direction.

11. The lens according to claim 10, wherein first conductors of the first pair of scan coils and second conductors of the second pair of scan coils partially overlap.

12. The lens according to claim 1, wherein the magnetic deflector provides two dipoles or provides an octupole.

13. The lens according to claim 1, wherein a coil of the first pair of scan coils includes two connecting portions, at least one connecting portion having a first width and a coil portion with split wires between the two connecting portions, wherein the split wires have a second width smaller than the first width.

14. The lens according to claim 13, wherein the second width is about one half to one third of the first width.

15. The lens according to claim 1, wherein the lens is an objective lens and further comprises:
a lens coil; and
a pole piece configured to guide a magnetic field of the lens coil, the liner tube being disposed within the pole piece.

16. A liner tube configured to be disposed in a lens of a charged particle beam apparatus, comprising:
at least a first conductive portion;
a ceramic portion adjacent the first conductive portion; and
one or more coating layers disposed on the ceramic portion in electrical contact with the first conductive portion,
wherein the first conductive portion is configured as a lens electrode.

17. A scanning charged particle beam apparatus, comprising:
a charged particle source configured to emit a primary charged particle beam;
a stage configured to support a specimen to be irradiated with the primary charged particle beam; and
a lens according to claim 1 configured to focus the primary charged particle beam on the specimen, wherein the magnetic deflector is configured to scan the primary charged particle beam over the specimen.

18. The scanning charged particle beam apparatus of claim 17, further comprising:
a beam boost tube extending at least partially through a column of the scanning charged particle beam apparatus in a direction from the charged particle source towards the lens, the beam boost tube being electrically connected to the first electrode.

19. A method of generating an image of a portion of a specimen with a scanning charged particle beam apparatus, comprising:
biasing a first electrode to provide a first potential to a first conductive portion through one or more coated layers disposed on a ceramic portion of a liner tube;
biasing a second electrode to a second potential to generate a lens effect between the first conductive portion and the second electrode; and
scanning a primary charged particle beam over the specimen with a magnetic deflector disposed outside of the liner tube.
